(19) United States
(12) Patent Application Publication
(10) Pub. No.: US 2026/0372197 A1
(43) Pub. Date: Nov. 19, 2026

(54) PACKAGE STRUCTURE WITH CONDUCTIVE VIA STRUCTURE

(71) Applicant: Taiwan Semiconductor Manufacturing Company, Ltd., Hsinchu (TW)

(72) Inventors: Tzu-Chun TANG, Kaohsiung City (TW); Wei-Ting CHEN, Tainan City (TW); Chung-Hao TSAI, Changhua County (TW); Chen-Hua YU, Hsinchu City (TW)

(21) Appl. No.: 19/752,935

(22) Filed: Jul. 24, 2026

Related U.S. Application Data
(62) Division of application No. 18/432,386, filed on Feb. 5, 2024.

(51) Int. Cl. H10W 90/00; F21V 8/00; H10W 70/63; H10W 74/10; H10W 72/00; H10W 72/90; H10W 80/00; H10W 90/20

(52) U.S. Cl. CPC H10W 90/00; G02B 6/0088; H10W 70/635; H10W 74/129; H10W 72/01351; H10W 72/9415; H10W 80/743; H10W 90/297; H10W 90/701; H10W 90/732; H10W 90/792

(57) ABSTRACT

A package structure is provided. The package structure includes a photonic substrate having a first bonding dielectric layer, multiple first bonding pads embedded in the first bonding dielectric layer, and a waveguide structure. The package structure also includes an electrical substrate having multiple active devices, a second bonding dielectric layer, and multiple second bonding pads embedded in the second bonding dielectric layer. A first interface between the second bonding dielectric layer and the first bonding dielectric layer meets a second interface between the second bonding pads and the first bonding pads. The package structure further includes a conductive via structure laterally surrounded by the photonic substrate and passing through the waveguide structure toward the electrical substrate. The conductive via structure vertically extends across a bottom of the first bonding dielectric layer.

### PRIORITY CLAIM AND CROSS-REFERENCE

This Application is a Divisional of U.S. Application No. 18/432,386, filed on Feb. 05, 2024, the entirety of which is incorporated by reference herein.

### BACKGROUND

Semiconductor devices are used in a variety of electronic applications, such as personal computers, cell phones, digital cameras, and other electronic equipment. Semiconductor devices are typically fabricated by sequentially depositing insulating layers or dielectric layers, conductive layers, and semiconductor layers over a semiconductor substrate, and patterning the various material layers using photolithography processes and etching processes to form circuit components and elements thereon.

Many integrated circuits (IC) are typically manufactured on a semiconductor wafer. Technological advances in IC materials and design have produced generations of ICs. Each generation has smaller and more complex circuits than the previous generation. The dies of the wafer may be processed and packaged at the wafer level, and various technologies have been developed for wafer level packaging. Since the chip package structure may need to include multiple chips with multiple functions, it is a challenge to form a reliable chip package structure with multiple chips and having a low current path resistance between the chips.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A-1J are cross-sectional views of various stages of a process for forming a chip package structure, in accordance with some embodiments.

FIGS. 2A-2D are cross-sectional views of various stages of a process for forming a chip package structure, in accordance with some embodiments.

FIG. 3 is a cross-sectional view of a chip package structure, in accordance with some embodiments.

FIG. 4 is a cross-sectional view of a chip package structure, in accordance with some embodiments.

FIG. 5 is a cross-sectional view of a chip package structure, in accordance with some embodiments.

FIG. 6 is a cross-sectional view of a chip package structure, in accordance with some embodiments.

FIG. 7 is a cross-sectional view of a chip package structure, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. The term “substantially” may be varied in different technologies and be in the deviation range understood by the skilled in the art. For example, the term “substantially” may also relate to 90 % of what is specified or higher, such as 95 % of what is specified or higher, especially 99 % of what is specified or higher, including 100 % of what is specified, though the present invention is not limited thereto. Furthermore, terms such as "substantially parallel" or "substantially perpendicular" may be interpreted as not to exclude insignificant deviation from the specified arrangement and may include for example deviations of up to 10°. The word "substantially" does not exclude "completely" e.g. a composition which is "substantially free" from Y may be completely free from Y.

The term "about" may be varied in different technologies and be in the deviation range understood by the skilled in the art. The term “about” in conjunction with a specific distance or size is to be interpreted so as not to exclude insignificant deviation from the specified distance or size. For example, the term “about” may include deviations of up to 10 % of what is specified, though the present invention is not limited thereto. The term "about" in relation to a numerical value x may mean x ±5 or 10 % of what is specified, though the present invention is not limited thereto.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

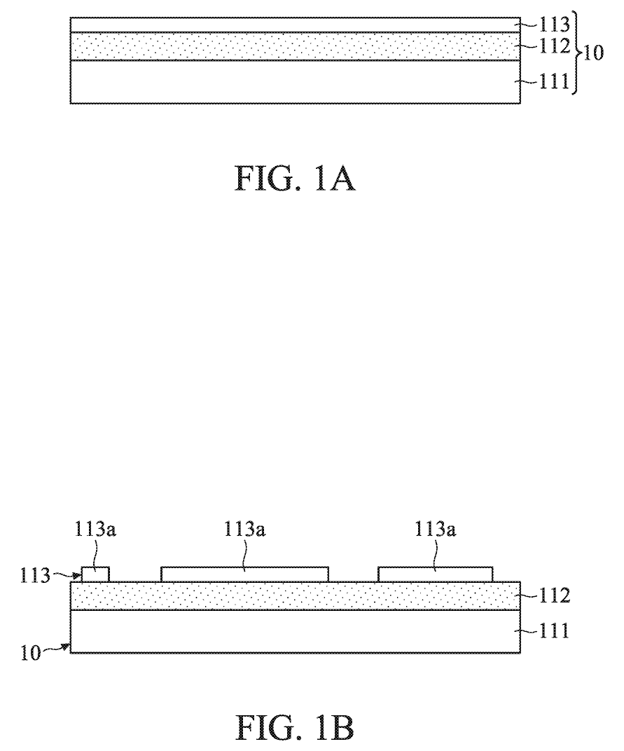

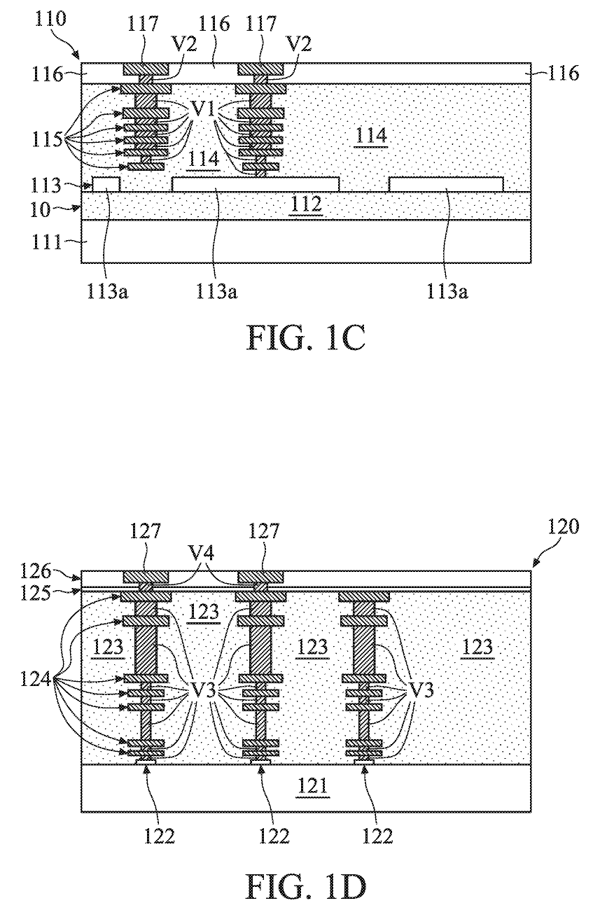

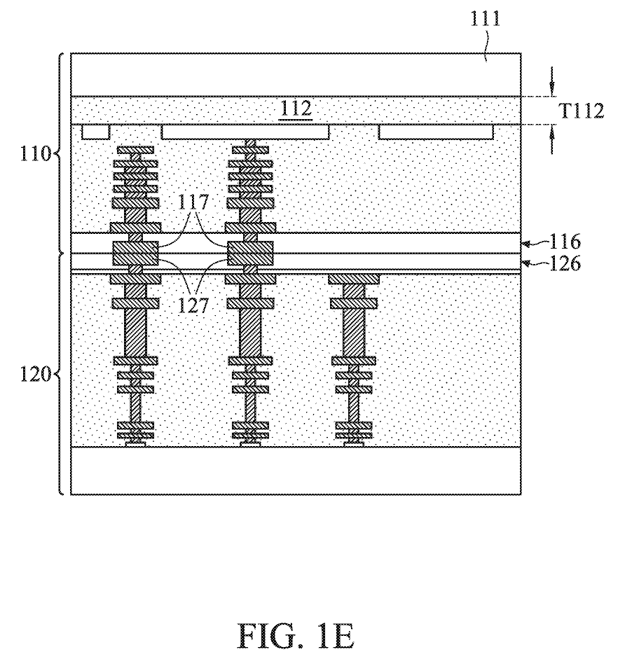

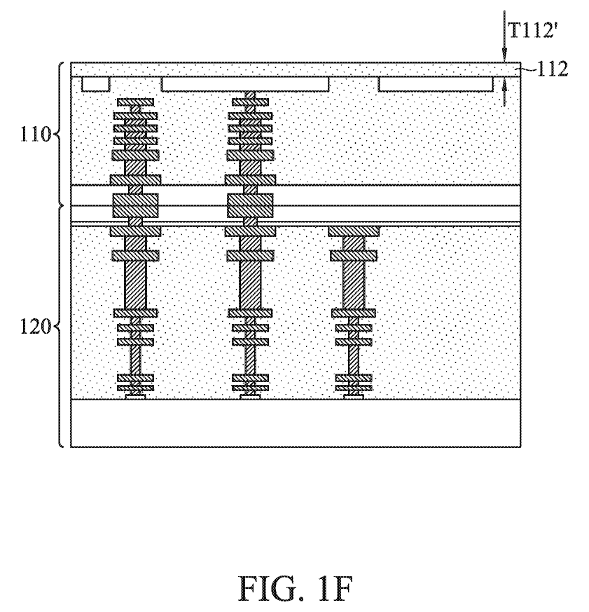

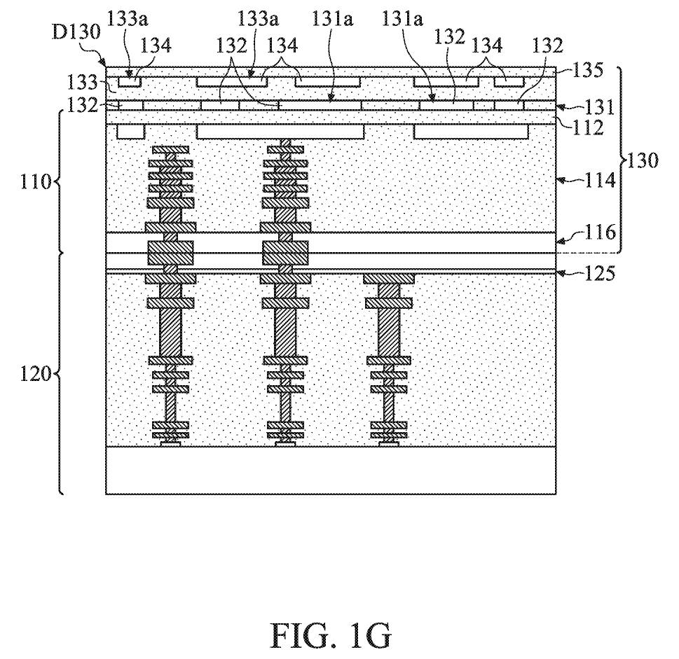

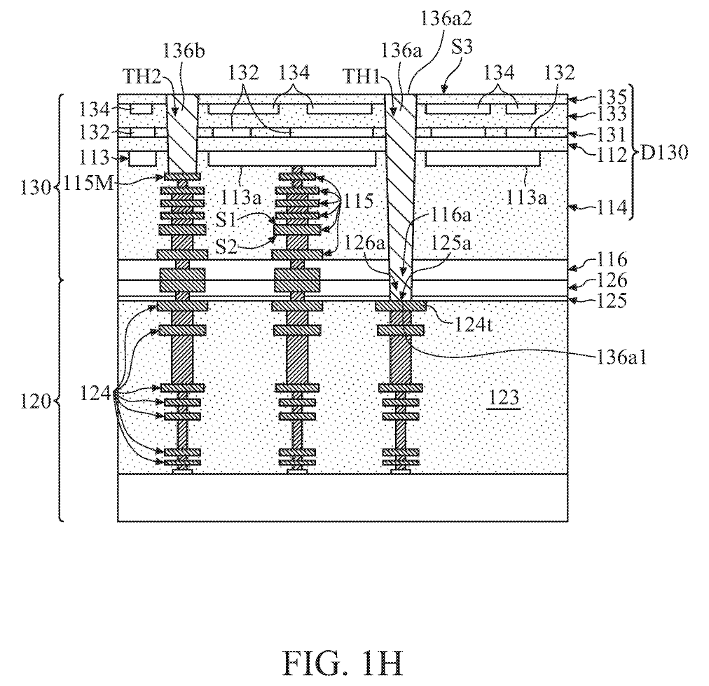

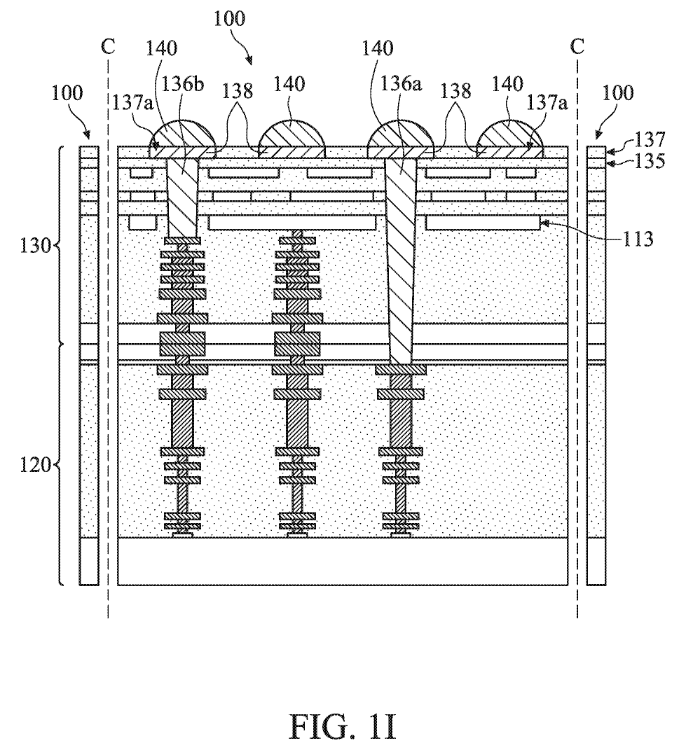

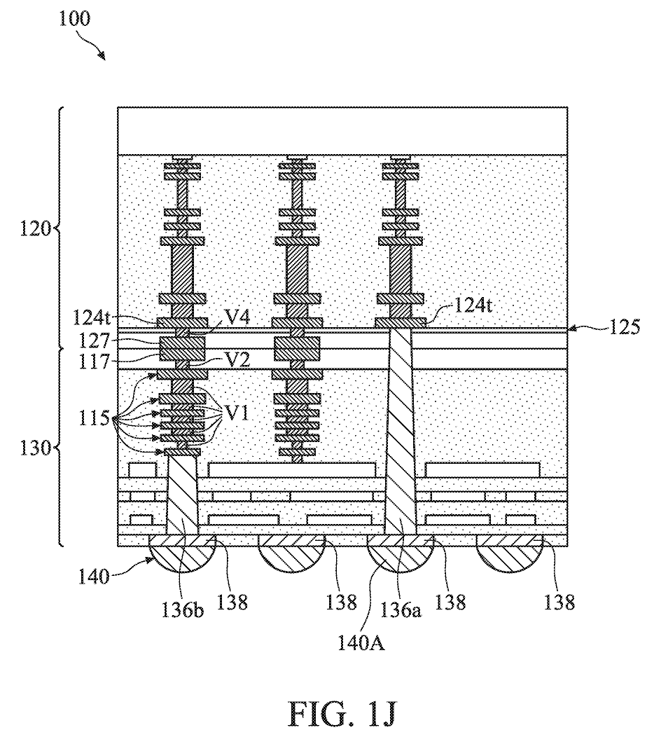

FIGS. 1A-1J are cross-sectional views of various stages of a process for forming a chip package structure, in accordance with some embodiments. As shown in FIG. 1A, a substrate 10 is provided, in accordance with some embodiments. The substrate 10 includes a semiconductor on insulator (SOI) substrate (such as silicon on insulator or germanium on insulator). The substrate 10 includes, for example, a wafer or a portion of a wafer.

The substrate 10 includes a semiconductor layer 111, an isolation layer 112, and a semiconductor layer 113, in accordance with some embodiments. The isolation layer 112 is between the semiconductor layers 111 and 113, in accordance with some embodiments. The semiconductor layer 111 is thicker than the semiconductor layer 113, in accordance with some embodiments.

In some embodiments, the semiconductor layers 111 and 113 are made of an elementary semiconductor material including silicon or germanium in a single crystal structure, a polycrystal structure, or an amorphous structure. In some other embodiments, the semiconductor layers 111 and 113 are made of a compound semiconductor, such as silicon carbide, gallium arsenide, gallium phosphide, indium phosphide, indium arsenide, an alloy semiconductor, such as SiGe or GaAsP, or a combination thereof.

In some embodiments, the various device elements are formed in and/or over the semiconductor layer 113. The device elements are not shown in figures for the purpose of simplicity and clarity. Examples of the various device elements include modulator devices or other suitable elements.

The isolation layer 112 is made of an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

Alternatively, the isolation layer 112 includes a low-k material or a porous dielectric material having a k-value which is lower than that of silicon oxide, or lower than about 3.0 or about 2.5, in accordance with some embodiments.

As shown in FIG. 1B, portions of the semiconductor layer 113 are removed, in accordance with some embodiments. The remaining portions of the semiconductor layer 113 form semiconductor structures 113a, in accordance with some embodiments.

The semiconductor structures 113a are spaced apart from each other, in accordance with some embodiments. The semiconductor structures 113a include modulator devices or other suitable elements, in accordance with some embodiments. The removal process includes a photolithography process and an etching process, in accordance with some embodiments.

As shown in FIG. 1C, a dielectric layer 114, wiring layers 115, and conductive vias V1 are formed over the substrate 10, in accordance with some embodiments. The wiring layers 115 and the conductive vias V1 are in the dielectric layer 114, in accordance with some embodiments.

The conductive vias V1 are connected between the wiring layers 115 and between the wiring layers 115 and the semiconductor structures 113a, in accordance with some embodiments. The wiring layers 115 are electrically connected to the semiconductor structures 113a, in accordance with some embodiments.

The dielectric layer 114 is made of an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

Alternatively, the dielectric layer 114 includes a low-k material or a porous dielectric material having a k-value which is lower than that of silicon oxide, or lower than about 3.0 or about 2.5, in accordance with some embodiments.

The dielectric layer 114 is formed using a chemical vapor deposition (CVD) process, such as a low-pressure CVD process, a plasma-enhanced CVD process, or a high-density plasma CVD process, an atomic layer deposition process, a spin-on process, a physical vapor deposition process, or another suitable process.

The wiring layers 115 are made of a conductive material, such as metal (e.g., copper, aluminum, gold, silver, or tungsten) or alloys thereof, in accordance with some embodiments. The conductive vias V1 are made of a conductive material, such as metal (e.g., copper, aluminum, gold, silver, or tungsten) or alloys thereof, in accordance with some embodiments.

As shown in FIG. 1C, a bonding dielectric layer 116, bonding pads 117, and conductive vias V2 are formed over the dielectric layer 114, in accordance with some embodiments. The bonding pads 117 and conductive vias V2 are formed in the bonding dielectric layer 116, in accordance with some embodiments. The conductive vias V2 are connected between the bonding pads 117 and the wiring layers 115, in accordance with some embodiments.

The bonding dielectric layer 116 is made of an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments. Alternatively, the bonding dielectric layer 116 includes a low-k material or a porous dielectric material having a k-value which is lower than that of silicon oxide, or lower than about 3.0 or about 2.5, in accordance with some embodiments.

The bonding dielectric layer 116 is formed using a chemical vapor deposition (CVD) process, such as a low-pressure CVD process, a plasma-enhanced CVD process, or a high-density plasma CVD process, an atomic layer deposition process, a spin-on process, a physical vapor deposition process, or another suitable process.

The bonding pads 117 are made of a conductive material, such as metal (e.g., copper, aluminum, gold, silver, or tungsten) or alloys thereof, in accordance with some embodiments. The conductive vias V2 are made of a conductive material, such as metal (e.g., copper, aluminum, gold, silver, or tungsten) or alloys thereof, in accordance with some embodiments. In this step, a substrate 110 is substantially formed, in accordance with some embodiments.

As shown in FIG. 1D, an electrical substrate 120 is provided, in accordance with some embodiments. The electrical substrate 120 is also referred to as an electrical integrated-circuit (EIC) substrate, in accordance with some embodiments. The electrical substrate 120 includes a substrate 121, devices 122, a dielectric structure 123, wiring layers 124, conductive vias V3, an etch stop layer 125, a bonding dielectric layer 126, bonding pads 127, and conductive vias V4, in accordance with some embodiments.

The substrate 121 is made of an elementary semiconductor material including silicon or germanium in a single crystal structure, a polycrystal structure, or an amorphous structure. In some other embodiments, the substrate 121 is made of a compound semiconductor, such as silicon carbide, gallium arsenide, gallium phosphide, indium phosphide, indium arsenide, an alloy semiconductor, such as SiGe or GaAsP, or a combination thereof.

In some embodiments, various devices 122 are formed in and/or over the substrate 121. Examples of the various devices 122 include active devices, passive devices, other suitable elements, or a combination thereof. The active devices may include transistors or diodes (not shown) formed at a surface of the substrate 121. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc. Various processes, such as front-end-of-line (FEOL) semiconductor fabrication processes, are performed to form the various devices 122. The FEOL semiconductor fabrication processes may include deposition, etching, implantation, photolithography, annealing, planarization, one or more other applicable processes, or a combination thereof.

In some embodiments, isolation features (not shown) are formed in the substrate 121. The isolation features are used to surround active regions and electrically isolate various devices 122 formed in and/or over the substrate 121 in the active regions. In some embodiments, the isolation features include shallow trench isolation (STI) features, local oxidation of silicon (LOCOS) features, other suitable isolation features, or a combination thereof.

The dielectric structure 123 is formed over the substrate 121 and the devices 122, in accordance with some embodiments. The wiring layers 124 and the conductive vias V3 are formed in the dielectric structure 123, in accordance with some embodiments. The conductive vias V3 are connected between the wiring layers 124 and between the wiring layers 124 and the devices 122, in accordance with some embodiments.

The dielectric structure 123 is made of an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments. Alternatively, the dielectric structure 123 includes a low-k material or a porous dielectric material having a k-value which is lower than that of silicon oxide, or lower than about 3.0 or about 2.5, in accordance with some embodiments.

The dielectric structure 123 is formed using a chemical vapor deposition (CVD) process, such as a low-pressure CVD process, a plasma-enhanced CVD process, or a high-density plasma CVD process, an atomic layer deposition process, a spin-on process, a physical vapor deposition process, or another suitable process.

The wiring layers 124 are made of a conductive material, such as metal (e.g., copper, aluminum, gold, silver, or tungsten) or alloys thereof, in accordance with some embodiments. The conductive vias V3 are made of a conductive material, such as metal (e.g., copper, aluminum, gold, silver, or tungsten) or alloys thereof, in accordance with some embodiments.

The etch stop layer 125 is formed over the wiring layers 124 and the dielectric structure 123, in accordance with some embodiments. The etch stop layer 125 is made of silicon nitride, silicon oxynitride, or the like, in accordance with some embodiments. The bonding dielectric layer 126 is formed over the etch stop layer 125, in accordance with some embodiments.

The bonding pads 127 is formed in the bonding dielectric layer 126, in accordance with some embodiments. The conductive vias V4 are connected between the bonding pads 127 and the wiring layers 124, in accordance with some embodiments. The conductive vias V4 pass through the etch stop layer 125 and the bonding dielectric layer 126, in accordance with some embodiments.

The bonding dielectric layer 126 is made of an oxide-containing material (e.g., silicon oxide), an oxynitride-containing material (e.g., silicon oxynitride), or the like, in accordance with some embodiments. The bonding pads 127 are made of a conductive material, such as metal (e.g., copper, aluminum, gold, silver, or tungsten) or alloys thereof, in accordance with some embodiments. The conductive vias V4 are made of a conductive material, such as metal (e.g., copper, aluminum, gold, silver, or tungsten) or alloys thereof, in accordance with some embodiments.

As shown in FIG. 1E, the substrate 110 is bonded to the electrical substrate 120, in accordance with some embodiments. The bonding pads 117 are bonded to the bonding pads 127, in accordance with some embodiments. The bonding dielectric layer 116 is bonded to the bonding dielectric layer 126, in accordance with some embodiments.

As shown in FIG. 1F, the semiconductor layer 111 is removed, in accordance with some embodiments. As shown in FIG. 1F, the isolation layer 112 is thinned, in accordance with some embodiments. That is, the thickness T112 of the isolation layer 112 of FIG. 1E is greater than the thickness T112’ of the isolation layer 112 of FIG. 1F, in accordance with some embodiments. The thinning process includes a planarization process such as a chemical mechanical polishing process, in accordance with some embodiments.

As shown in FIG. 1G, a dielectric layer 131 and waveguide structures 132 are formed over the isolation layer 112, in accordance with some embodiments. The waveguide structures 132 are formed in recesses 131a of the dielectric layer 131, in accordance with some embodiments.

The dielectric layer 131 is made of an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

Alternatively, the dielectric layer 131 includes a low-k material or a porous dielectric material having a k-value which is lower than that of silicon oxide, or lower than about 3.0 or about 2.5, in accordance with some embodiments.

The waveguide structures 132 are made of silicon nitride or another suitable waveguide material, in accordance with some embodiments. The waveguide structures 132 are formed using a deposition process and a chemical mechanical polishing process, in accordance with some embodiments.

As shown in FIG. 1G, a dielectric layer 133 and waveguide structures 134 are formed over the dielectric layer 131 and the waveguide structures 132, in accordance with some embodiments. The waveguide structures 134 are formed in recesses 133a of the dielectric layer 133, in accordance with some embodiments.

The dielectric layer 133 is made of an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

Alternatively, the dielectric layer 133 includes a low-k material or a porous dielectric material having a k-value which is lower than that of silicon oxide, or lower than about 3.0 or about 2.5, in accordance with some embodiments.

The waveguide structures 134 are made of silicon nitride or another suitable waveguide material, in accordance with some embodiments. The waveguide structures 134 are formed using a deposition process and a chemical mechanical polishing process, in accordance with some embodiments.

As shown in FIG. 1G, a dielectric layer 135 is formed over the dielectric layer 133 and the waveguide structures 134, in accordance with some embodiments. The dielectric layers 112, 114, 131, 133 and 135 and the bonding dielectric layer 116 together form a dielectric structure D130, in accordance with some embodiments.

The dielectric layer 135 is made of an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

In this step, a photonic substrate 130 is substantially formed, in accordance with some embodiments. The photonic substrate 130 is also referred to as a photonic integrated-circuit (PIC) substrate, in accordance with some embodiments. In some embodiments, the photonic substrate 130 does not include transistors. In some embodiments, the electrical substrate 120 includes more transistors than the photonic substrate 130.

As shown in FIG. 1H, portions of the dielectric structure D130 are removed to form through holes TH1 and TH2 in the dielectric structure D130, in accordance with some embodiments. The through hole TH2 exposes the wiring layer 115M of the wiring layers 115, in accordance with some embodiments.

The wiring layer 115M is the layer closest to the semiconductor layer 113 among the wiring layers 115, in accordance with some embodiments. The removal process includes a photolithography process and an etching process, in accordance with some embodiments.

As shown in FIG. 1H, portions of the bonding dielectric layers 116 and 126 are removed through the through hole TH1 to form a recess 116a in the bonding dielectric layer 116 and a recess 126a in the bonding dielectric layer 126, in accordance with some embodiments. The removal process includes a photolithography process and an etching process, in accordance with some embodiments.

As shown in FIG. 1H, a portion of the etch stop layer 125 is removed through the through hole TH1 to form a recess 125a in the etch stop layer 125, in accordance with some embodiments. The recess 125a exposes the wiring layer 124t of the wiring layers 124, in accordance with some embodiments.

The wiring layer 124t is the layer closest to the photonic substrate 130 among the wiring layers 124, in accordance with some embodiments. The removal process includes a photolithography process and an etching process, in accordance with some embodiments.

As shown in FIG. 1H, a conductive via structure 136a is formed in the through hole TH1 and the recesses 116a, 126a, and 125a, and a conductive via structure 136b is formed in the through hole TH2, in accordance with some embodiments.

The conductive via structure 136a passing through the dielectric structure D130, the bonding dielectric layers 116 and 126, and the etch stop layer 125, in accordance with some embodiments. The conductive via structure 136a is in direct contact with the wiring layer 124t, in accordance with some embodiments. The dielectric structure D130 separates the conductive via structure 136a from the semiconductor structures 113a, in accordance with some embodiments.

Each wiring layer 115 has opposite surfaces S1 and S2, in accordance with some embodiments. The surface S2 faces the bonding dielectric layer 116, in accordance with some embodiments. The conductive via structure 136a extends across the surfaces S1 and S2 of the wiring layer 115, in accordance with some embodiments.

The conductive via structure 136a has end portions 136a1 and 136a2, in accordance with some embodiments. The end portion 136a1 is closer to the bonding dielectric layer 116 than the wiring layer 115M, in accordance with some embodiments. The end portion 136a1 extends toward the electrical substrate 120, in accordance with some embodiments. The wiring layer 115M is closer to the surface S3 of the dielectric structure D130 than the end portion 136a1 of the conductive via structure 136a, in accordance with some embodiments.

The dielectric structure D130 has a surface S3 facing away from the electrical substrate 120, in accordance with some embodiments. The end portion 136a2 of the conductive via structure 136a is closer to the surface S3 than the waveguide structures 132 and 134, in accordance with some embodiments. The end portion 136a2 of the conductive via structure 136a is closer to the surface S3 of the dielectric structure D130 than the wiring layers 115, in accordance with some embodiments.

The conductive via structures 136a and 136b are made of a conductive material, such as metal (e.g., copper, aluminum, gold, silver, or tungsten) or alloys thereof, in accordance with some embodiments. The conductive via structures 136a and 136b are formed using a deposition process and a chemical mechanical polishing process, in accordance with some embodiments.

As shown in FIG. 1I, a dielectric layer 137 and bonding pads 138 are formed over the dielectric layer 135, in accordance with some embodiments. The bonding pads 138 are formed in recesses 137a of the dielectric layer 137, in accordance with some embodiments.

The dielectric layer 137 is made of an oxide-containing material (e.g., silicon oxide or tetraethyl orthosilicate (TEOS) oxide), an oxynitride-containing material (e.g., silicon oxynitride), a glass material (e.g., borosilicate glass (BSG), phosphoric silicate glass (PSG), borophosphosilicate glass (BPSG), or fluorinated silicate glass (FSG)), or a combination thereof, in accordance with some embodiments.

Alternatively, the dielectric layer 137 includes a low-k material or a porous dielectric material having a k-value which is lower than that of silicon oxide, or lower than about 3.0 or about 2.5, in accordance with some embodiments. The bonding pads 138 are made of a conductive material, such as metal (e.g., copper, aluminum, gold, silver, or tungsten) or alloys thereof, in accordance with some embodiments.

As shown in FIG. 1I, conductive bumps 140 are formed over the bonding pads 138, in accordance with some embodiments. The conductive bumps 140 are made of a conductive material, such as a solder material (e.g., tin or alloys thereof), in accordance with some embodiments. The conductive bumps 140 are made of metal (e.g., copper, aluminum, gold, silver, or tungsten) or alloys thereof, in accordance with some embodiments.

As shown in FIG. 1I, a cutting process is performed along cutting lines C to cut through the photonic substrate 130 and the electrical substrate 120 so as to form chip package structures 100, in accordance with some embodiments.

As shown in FIG. 1J, one of the chip package structures 100 is flipped upside down, in accordance with some embodiments. Since the conductive bump 140A of the conductive bumps 140 is electrically connected to the wiring layer 124t only through the bonding pad 138 and the conductive via structure 136a, without through the wiring layers 115, the conductive vias V1, V2 and V4, and the bonding pads 117 and 127, the current path resistance between the conductive bump 140A and the wiring layer 124t is reduced, in accordance with some embodiments. Therefore, the performance of the chip package structures 100 is improved, in accordance with some embodiments.

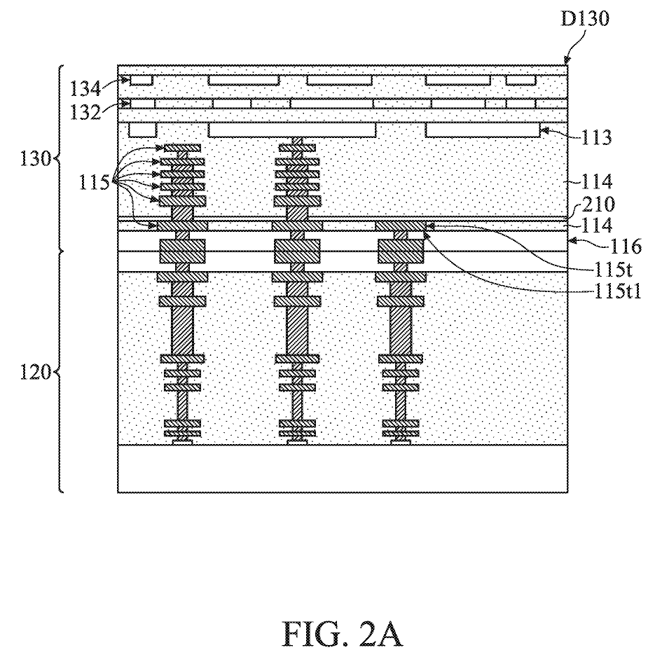

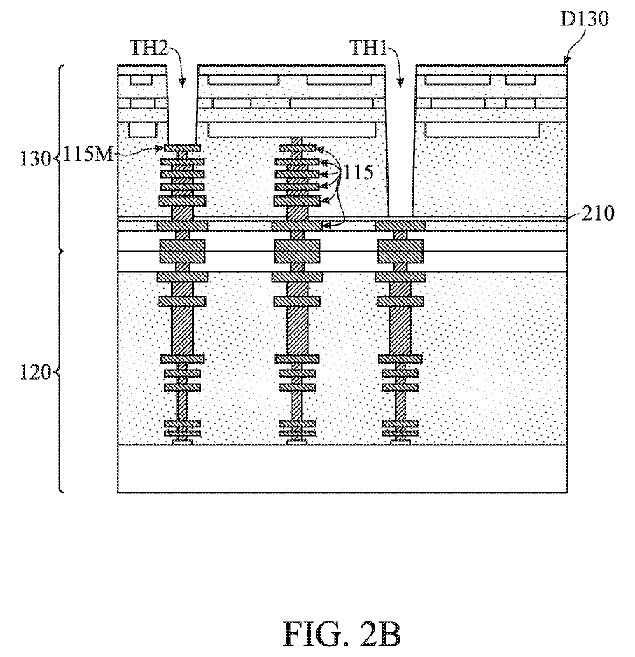

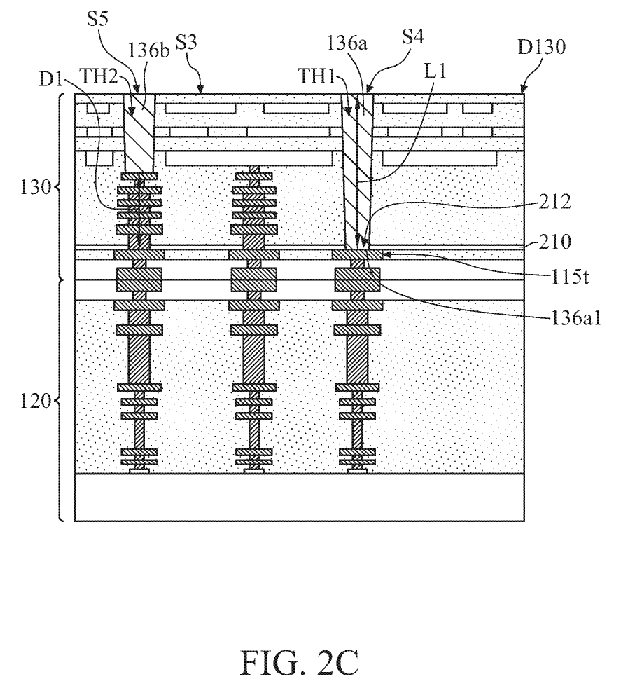

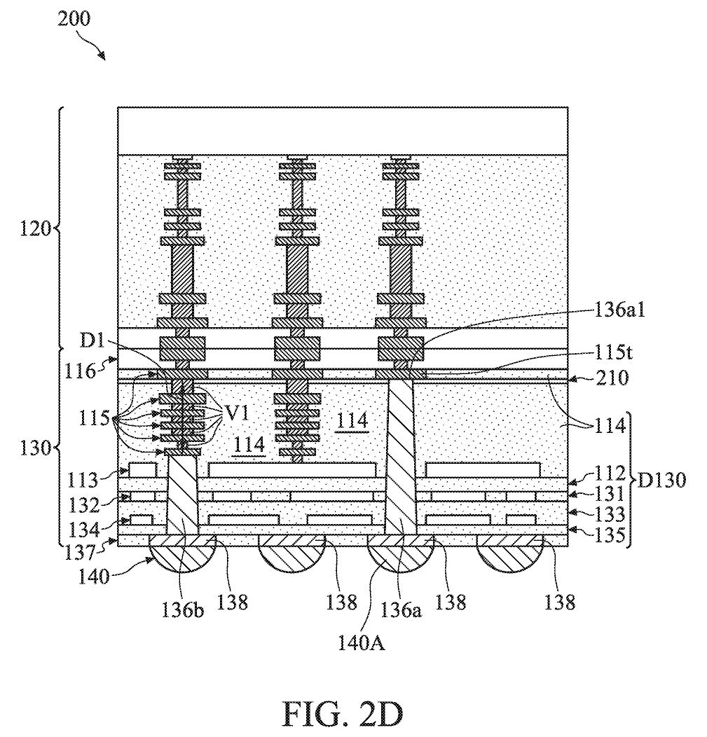

FIGS. 2A-2D are cross-sectional views of various stages of a process for forming a chip package structure, in accordance with some embodiments. As shown in FIG. 2A, the step of FIG. 1G is performed, in accordance with some embodiments.

The photonic substrate 130 of FIG. 2A is similar to the photonic substrate 130 of FIG. 1G, except that the photonic substrate 130 of FIG. 2A further includes an etch stop layer 210 in the dielectric layer 114 and over the wiring layer 115t, and the electrical substrate 120 of FIG. 2A does not include the etch stop layer 125 of the electrical substrate 120 of FIG. 1G, in accordance with some embodiments.

The wiring layer 115t is the layer closest to the electrical substrate 120 among the wiring layers 115, in accordance with some embodiments. The dielectric structure D130 exposes a surface 115t1 of the wiring layer 115t, in accordance with some embodiments.

The wiring layer 115t is between the etch stop layer 210 and the bonding dielectric layer 116, in accordance with some embodiments. The wiring layer 115t is in direct contact with the bonding dielectric layer 116, in accordance with some embodiments. The etch stop layer 210 is made of silicon nitride, silicon oxynitride, or the like, in accordance with some embodiments.

As shown in FIG. 2B, portions of the dielectric structure D130 are removed to form through holes TH1 and TH2 in the dielectric structure D130, in accordance with some embodiments. The through hole TH2 exposes the wiring layer 115M of the wiring layers 115, in accordance with some embodiments. The removal process includes a photolithography process and an etching process, in accordance with some embodiments.

As shown in FIG. 2C, a portion of the etch stop layer 210 is removed through the through hole TH1 to form a recess 212 in the etch stop layer 210 and exposing a portion of the wiring layer 115t, in accordance with some embodiments. The removal process includes a photolithography process and an etching process, in accordance with some embodiments.

As shown in FIG. 2C, a conductive via structure 136a is formed in the through hole TH1 and the recess 212, and a conductive via structure 136b is formed in the through hole TH2, in accordance with some embodiments. The end portion 136a1 of the conductive via structure 136a is in direct contact with the wiring layer 115t, in accordance with some embodiments.

The conductive via structure 136b is spaced apart from the wiring layer 115t by a distance D1, and a length L1 of the conductive via structure 136a is greater than the distance D1, in accordance with some embodiments. The surface S3 of the dielectric structure D130, an end surface S4 of the conductive via structure 136a, and an end surface S5 of the conductive via structure 136b are substantially level with each other, in accordance with some embodiments. The conductive via structure 136a is longer than the conductive via structure 136b, in accordance with some embodiments.

As shown in FIG. 2D, the steps of FIGS. 1I-1J are performed to form the dielectric layer 137, the bonding pads 138, and the conductive bumps 140, in accordance with some embodiments. In this step, a chip package structure 200 is substantially formed, in accordance with some embodiments.

Since the conductive bump 140A of the conductive bumps 140 is electrically connected to the wiring layer 115t only through the bonding pad 138 and the conductive via structure 136a, without through the wiring layers 115 under the wiring layer 115t and the conductive vias V1, the current path resistance between the conductive bump 140A and the wiring layer 115t is reduced, in accordance with some embodiments. Therefore, the performance of the chip package structures 200 is improved, in accordance with some embodiments.

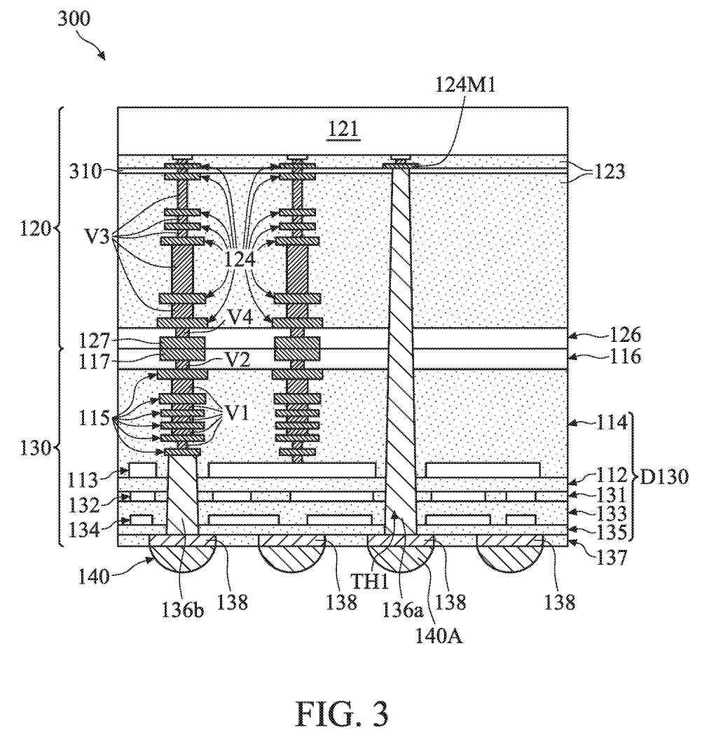

FIG. 3 is a cross-sectional view of a chip package structure 300, in accordance with some embodiments. As shown in FIG. 3, the chip package structure 300 is similar to the chip package structure 100 of FIG. 1J, except that the conductive via structure 136a of the chip package structure 300 further extends into the dielectric structure 123, in accordance with some embodiments.

The chip package structure 300 further includes an etch stop layer 310 in the dielectric structure 123 and under the wiring layer 124M1 of the wiring layers 124, in accordance with some embodiments. The wiring layer 124M1 is the layer closest to the substrate 121 among the wiring layers 124, in accordance with some embodiments.

The conductive via structure 136a passes through the dielectric structure D130, the bonding dielectric layers 116 and 126, the dielectric structure 123, and the etch stop layer 310, in accordance with some embodiments. The conductive via structure 136a is in direct contact with the wiring layer 124M1, in accordance with some embodiments. The conductive via structure 136a is in direct contact with the dielectric structure 123, in accordance with some embodiments.

Since the conductive bump 140A of the conductive bumps 140 is electrically connected to the wiring layer 124M1 only through the bonding pad 138 and the conductive via structure 136a, without through the wiring layers 115 and 124, the conductive vias V1, V2, V3, and V4, and the bonding pads 117 and 127, the current path resistance between the conductive bump 140A and the wiring layer 124M1 is reduced, in accordance with some embodiments. Therefore, the performance of the chip package structures 300 is improved, in accordance with some embodiments.

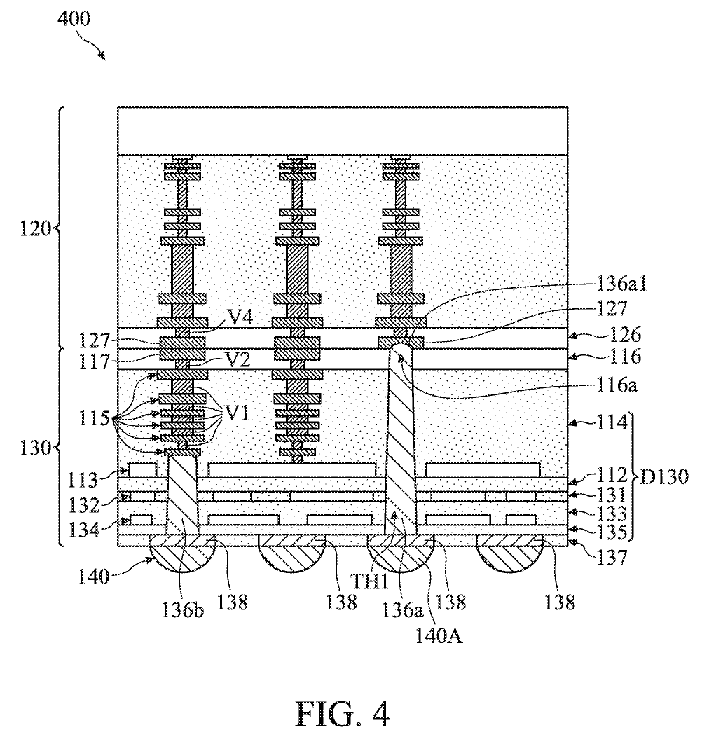

FIG. 4 is a cross-sectional view of a chip package structure 400, in accordance with some embodiments. As shown in FIG. 4, the chip package structure 400 is similar to the chip package structure 200 of FIG. 2D, except that the conductive via structure 136a of the chip package structure 400 passes through the dielectric structure D130 and the bonding dielectric layer 116, in accordance with some embodiments.

The conductive via structure 136a is formed in the through hole TH1 of the dielectric structure D130 and the recess 116a of the bonding dielectric layer 116, in accordance with some embodiments. The end portion 136a1 is in direct contact with the bonding pad 127, in accordance with some embodiments. The end portion 136a1 of the conductive via structure 136a extends into the bonding pad 127 of the electrical substrate 120, in accordance with some embodiments.

Since the conductive bump 140A of the conductive bumps 140 is electrically connected to the bonding pad 127 only through the bonding pad 138 and the conductive via structure 136a, without through the wiring layers 115, the conductive vias V1 and V2, and the bonding pad 117, the current path resistance between the conductive bump 140A and the bonding pad 127 is reduced, in accordance with some embodiments. Therefore, the performance of the chip package structures 400 is improved, in accordance with some embodiments.

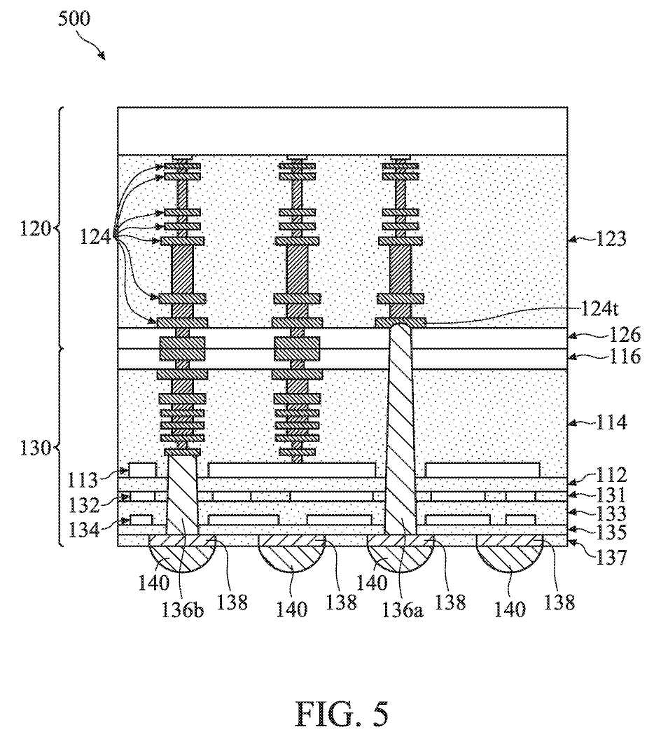

FIG. 5 is a cross-sectional view of a chip package structure 500, in accordance with some embodiments. As shown in FIG. 5, the chip package structure 500 is similar to the chip package structure 100 of FIG. 1J, except that the electrical substrate 120 does not have the etch stop layer 125 of FIG. 1J, and the conductive via structure 136a of the chip package structure 500 extends into the wiring layer 124t, in accordance with some embodiments.

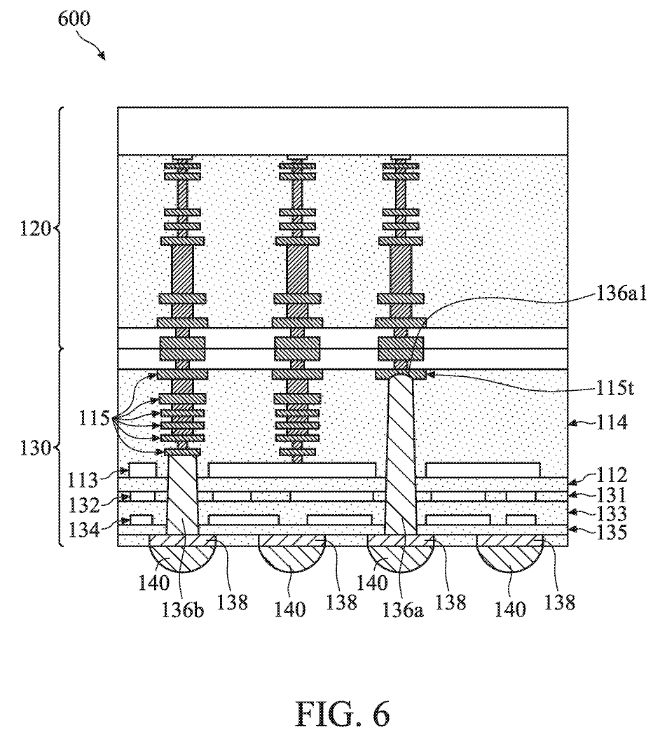

FIG. 6 is a cross-sectional view of a chip package structure 600, in accordance with some embodiments. As shown in FIG. 6, the chip package structure 600 is similar to the chip package structure 200 of FIG. 2D, except that the photonic substrate 130 does not have the etch stop layer 210 of FIG. 2D, and the end portion 136a1 of the conductive via structure 136a of the chip package structure 600 extends into the wiring layer 115t, in accordance with some embodiments. The conductive via structure 136a is in direct contact with the wiring layer 115t, in accordance with some embodiments.

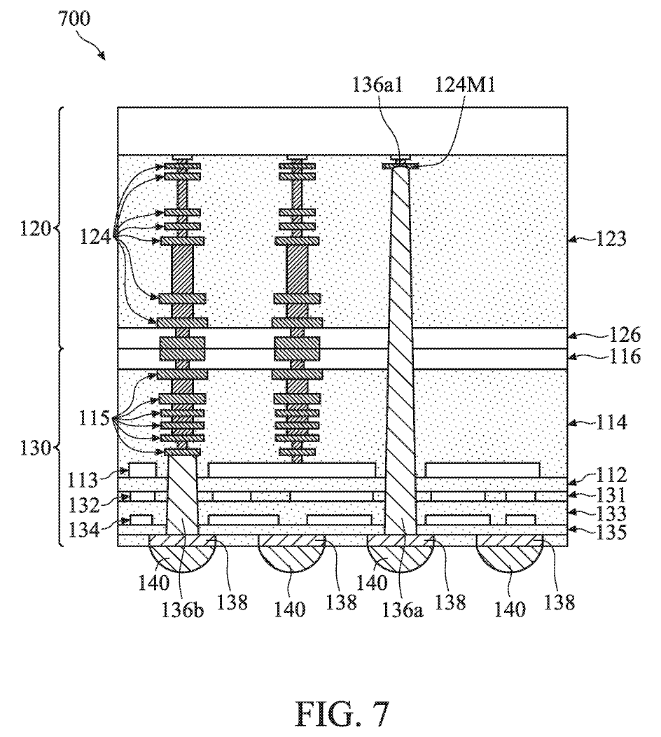

FIG. 7 is a cross-sectional view of a chip package structure 700, in accordance with some embodiments. As shown in FIG. 7, the chip package structure 700 is similar to the chip package structure 300 of FIG. 3, except that the electrical substrate 120 does not have the etch stop layer 310 of FIG. 3, and the end portion 136a1 of the conductive via structure 136a of the chip package structure 700 extends into the wiring layer 124M1, in accordance with some embodiments. The conductive via structure 136a is in direct contact with the wiring layer 124M1, in accordance with some embodiments.

Processes and materials for forming the chip package structures 200, 300, 400, 500, 600, and 700 may be similar to, or the same as, those for forming the chip package structure 100 described above. Elements designated by the same or similar reference numbers as those in FIGS. 1A-7 have the same or similar structures and the materials. Therefore, the detailed descriptions thereof will not be repeated herein.

In accordance with some embodiments, chip package structures and methods for forming the same are provided. The methods (for forming the chip package structure) form a long conductive via structure passing through a photonic integrated-circuit (PIC) substrate to be electrically connected to an electrical integrated-circuit (EIC) substrate. Since a conductive bump under the photonic integrated-circuit substrate and the long conductive via structure is electrically connected to the electrical integrated-circuit substrate only through a bonding pad and the long conductive via structure, without through wiring layers, conductive vias, and the bonding pads, the current path resistance between the conductive bump and the electrical integrated-circuit substrate is reduced. Therefore, the performance of the chip package structures is improved.

In accordance with some embodiments, a method for forming a chip package structure is provided. The method includes providing an electrical substrate and a photonic substrate over and bonded to the electrical substrate. The electrical substrate includes a first bonding dielectric layer and a first bonding pad embedded in the first bonding dielectric layer. The photonic substrate includes a second bonding dielectric layer, a second bonding pad, a dielectric structure, a first wiring layer, and a waveguide structure, the second bonding pad is embedded in the second bonding dielectric layer and bonded to the first bonding pad, the dielectric structure is over the second bonding dielectric layer, the first wiring layer and the waveguide structure are in the dielectric structure, the first wiring layer is between the waveguide structure and the second bonding dielectric layer, and the first wiring layer is in direct contact with the second bonding dielectric layer. The method includes partially removing the dielectric structure to form a first through hole and a second through hole in the dielectric structure. The first through hole passes through the dielectric structure and exposes the first wiring layer. The method includes forming a first conductive via structure and a second conductive via structure in the first through hole and the second through hole respectively. The first conductive via structure is in direct contact with the first wiring layer, and the second conductive via structure is spaced apart from the first wiring layer.

In accordance with some embodiments, a method for forming a chip package structure is provided. The method includes providing an electrical substrate and a photonic substrate over and bonded to the electrical substrate. The electrical substrate includes a first bonding dielectric layer and a first bonding pad embedded in the first bonding dielectric layer. The photonic substrate includes a second bonding dielectric layer, a second bonding pad, a first dielectric structure, and a waveguide structure, the second bonding pad is embedded in the second bonding dielectric layer and bonded to the first bonding pad, the first dielectric structure is over the second bonding dielectric layer, and the waveguide structure is in the first dielectric structure. The method includes partially removing the first dielectric structure, the second bonding dielectric layer, and the first bonding dielectric layer to form a through hole passing through the first dielectric structure, the second bonding dielectric layer, and the first bonding dielectric layer. The method includes forming a conductive via structure in the through hole.

In accordance with some embodiments, a chip package structure is provided. The chip package structure includes a photonic substrate including a first bonding dielectric layer, a first bonding pad, a first dielectric structure, a first wiring layer, and a waveguide structure. The first wiring layer and the waveguide structure are in the first dielectric structure, the first wiring layer has a first surface and a second surface opposite to the first surface, the first bonding dielectric layer is over the first dielectric structure, the second surface faces the first bonding dielectric layer, and the first bonding pad is embedded in the first bonding dielectric layer. The chip package structure includes an electrical substrate bonded to the photonic substrate. The electrical substrate includes a second bonding dielectric layer and a second bonding pad embedded in the second bonding dielectric layer, and the second bonding pad is bonded to the first bonding pad. The chip package structure includes a conductive via structure passing through the first dielectric structure and extending across the first surface and the second surface of the first wiring layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a photonic substrate comprising a first bonding dielectric layer, a first bonding pad, a first dielectric structure, a first wiring layer, and a waveguide structure, wherein the first wiring layer and the waveguide structure are in the first dielectric structure, the first wiring layer has a first surface and a second surface opposite to the first surface, the first bonding dielectric layer is over the first dielectric structure, the second surface faces the first bonding dielectric layer, and the first bonding pad is embedded in the first bonding dielectric layer;
an electrical substrate bonded to the photonic substrate, wherein the electrical substrate comprises a second bonding dielectric layer and a second bonding pad embedded in the second bonding dielectric layer, and the second bonding pad is bonded to the first bonding pad; and
a conductive via structure passing through the first dielectric structure and extending across the first surface and the second surface of the first wiring layer.

2. The package structure as claimed in claim 1, wherein the conductive via structure continuously passes through the first dielectric structure and the first bonding dielectric layer.

3. The package structure as claimed in claim 2, wherein the conductive via structure is in direct contact with the second bonding pad.

4. The package structure as claimed in claim 1, wherein the photonic substrate further comprises:
a second wiring layer in the first dielectric structure, wherein the first dielectric structure exposes a surface of the second wiring layer, and the conductive via structure is in direct contact with the second wiring layer.

5. The package structure as claimed in claim 1, wherein the electrical substrate further comprises:
a second wiring layer over the second bonding dielectric layer, wherein
the conductive via structure continuously passes through the first dielectric structure, the first bonding dielectric layer, and the second bonding dielectric layer and is in direct contact with the second wiring layer.

6. The package structure as claimed in claim 1, further comprising:
a second conductive via structure extending into the first dielectric structure and passing through the waveguide structure.

7. The package structure as claimed in claim 6, wherein the conductive via structure is taller than the second conductive via structure.

8. The package structure as claimed in claim 6, wherein the second conductive via structure has a first end and a second end opposite to the first end, and the second end of the second conductive via structure is vertically located between the first end of the second conductive via structure and a top of the conductive via structure.

9. The package structure as claimed in claim 1, wherein the conductive via structure has a convex top surface curved toward the electrical substrate.

10. The package structure as claimed in claim 1, wherein the conductive via structure is taller than the photonic substrate.

11. A package structure, comprising:
a photonic substrate having a first bonding dielectric layer, a plurality of first bonding pads embedded in the first bonding dielectric layer, and a waveguide structure;
an electrical substrate having a second bonding dielectric layer and a plurality of second bonding pads embedded in the second bonding dielectric layer, wherein the second bonding dielectric layer is bonded to the first bonding dielectric layer, and the second bonding pads are bonded to the first bonding pads; and
a conductive via structure extending from a surface of the photonic substrate toward the electrical substrate, wherein the conductive via structure is taller than the photonic substrate.

12. The package structure as claimed in claim 11, wherein the conductive via structure has a convex top surface curved toward the electrical substrate.

13. The package structure as claimed in claim 11, further comprising:
a conductive bump below the photonic substrate, wherein the conductive bump is electrically connected to the conductive via structure.

14. The package structure as claimed in claim 13, wherein the conductive bump is substantially vertically aligned with the conductive via structure.

15. The package structure as claimed in claim 11, further comprising:
a second conductive via structure extending from the surface of the photonic substrate toward the electrical substrate and passing through the waveguide structure, wherein the conductive via structure is taller than the second conductive via structure.

16. A package structure, comprising:
a photonic substrate having a first bonding dielectric layer, a plurality of first bonding pads embedded in the first bonding dielectric layer, and a waveguide structure;
an electrical substrate having a plurality of active devices, a second bonding dielectric layer, and a plurality of second bonding pads embedded in the second bonding dielectric layer, wherein a first interface between the second bonding dielectric layer and the first bonding dielectric layer meets a second interface between the second bonding pads and the first bonding pads; and
a conductive via structure laterally surrounded by the photonic substrate and passing through the waveguide structure toward the electrical substrate, wherein the conductive via structure vertically extends across a bottom of the first bonding dielectric layer.

17. The package structure as claimed in claim 16, wherein the conductive via structure protrudes from the first interface between the second bonding dielectric layer and the first bonding dielectric layer and is partially surrounded by the second bonding dielectric layer.

18. The package structure as claimed in claim 16, wherein the conductive via structure has a convex top surface curved toward one of the active devices.

19. The package structure as claimed in claim 16, wherein the conductive via structure has a slanted sidewall.

20. The package structure as claimed in claim 16, wherein the conductive via structure penetrates through opposite surfaces of the second bonding dielectric layer.
